(19) United States
(12) Patent Application Publication
(10) Pub. No.: US 2026/0332125 A1
(43) Pub. Date: Oct. 22, 2026

(54) INVERTED BULK ACOUSTIC RESONATOR

(71) Applicant: Murata Manufacturing Co., Ltd., Nagaokakyo-shi (JP)

(72) Inventors: John KOULAKIS, Los Angeles, CA (US); Patrick Turner, Portola Valley, CA (US)

(21) Appl. No.: 19/647,333

(22) Filed: Apr. 14, 2026

Related U.S. Application Data
(60) Provisional application No. 63/790,838, filed on Apr. 18, 2025.

(51) Int. Cl. H03H 9/17; H03H 9/02; H03H 9/56

(52) U.S. Cl. CPC H03H 9/172; H03H 9/02015; H03H 9/02228; H03H 9/568

(57) ABSTRACT

A bulk acoustic resonator such as a bulk acoustic resonator is provided. The bulk acoustic resonator includes a piezoelectric layer, a substrate, and an interdigital transducer (IDT) including a plurality of interleaved fingers including a first plurality of fingers and a second plurality of fingers that are interleaved and are substantially parallel along a first axis. The IDT is disposed between the piezoelectric layer and the substrate, the first and second plurality of fingers overlap for a distance O along the first axis, and a size AP of the piezoelectric layer along the first axis is less than or equal to the distance O.

### CROSS REFERENCE TO RELATED APPLICATIONS

This application claims priority to U.S. Patent Provisional No. 63/790,838, filed Apr. 18, 2025, the entire contents of which are hereby incorporated by reference.

### TECHNICAL FIELD

This disclosure relates inverted transversely-excited film bulk acoustic resonators (iXBARs) and radio frequency (RF) filters including the same.

### BACKGROUND

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “passband” of the filter. The range of frequencies stopped by such a filter is referred to as the “stop-band” of the filter. A typical RF filter has at least one passband and at least one stop-band. Specific requirements on a passband or stop-band may depend on the specific application. For example, in some cases a “passband” may be defined as a frequency range where the insertion loss of a filter is better than a defined value such as 1 dB, 2 dB, or 3 dB, while a “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

Performance enhancements to the RF filters in a wireless system can have a broad impact to system performance. Improvements in RF filters can be leveraged to provide system performance improvements, such as larger cell size, longer battery life, higher data rates, greater network capacity, lower cost, enhanced security, higher reliability, etc. These improvements can be realized at many levels of the wireless system both separately and in combination, for example, at the RF module, RF transceiver, mobile or fixed sub-system, or network levels. As the demand for RF filters operating at higher frequencies continues to increase, there is a need for improved filters that can operate at different frequency bands while also improving the manufacturing processes for making such filters.

In general, an inverted transversely-excited film bulk acoustic resonator (iXBAR) is an acoustic resonator structure for use in microwave filters. An iXBAR resonator typically comprises an interdigital transducer (IDT) formed on a substrate. The IDT can be disposed between a piezoelectric layer, for exampling, including a single-crystal piezoelectric material and the substrate. The IDT includes a first set of parallel fingers, extending from a first busbar and a second set of parallel fingers extending from a second busbar. The first and second sets of parallel fingers are interleaved. A microwave signal applied to the IDT excites a shear primary acoustic wave in the piezoelectric layer. iXBAR resonators provide high frequency capability and good power handling capabilities. iXBAR resonators may be used in a variety of RF filters including band-reject filters, bandpass filters, duplexers, and multiplexers. iXBARs are well suited for use in filters for communications bands with frequencies above 3 GHz.

However, in order to provide the type of high-level performance required by the above-described communications applications, potential electromechanical coupling loss mechanisms that detract from the performance of the RF filters may need to be addressed.

### SUMMARY

Exemplary aspects of the disclosure include a bulk acoustic resonator such as a bulk acoustic resonator (iXBAR) and a filter including the same. The bulk acoustic resonator includes a piezoelectric layer, a substrate, and an interdigital transducer (IDT) including a plurality of interleaved fingers including a first plurality of fingers and a second plurality of fingers that are interleaved and are substantially parallel along a first axis. The IDT is disposed between the piezoelectric layer and the substrate. The first and second plurality of fingers overlap for a distance O along the first axis. size AP of the piezoelectric layer along the first axis is less than or equal to the distance O.

Exemplary aspects of the disclosure include a bandpass filter. In an aspect, the bandpass filter includes a plurality of acoustic resonators comprising one or more series resonators and one or more shunt resonators. One of the one or more series resonators includes a first inverted transversely-excited bulk acoustic resonator (iXBAR). The first iXBAR includes a first piezoelectric layer, a first substrate including a first bulk portion and a first plurality of pillars, and a first interdigital transducer (IDT) including a first plurality of interleaved fingers. The first plurality of pillars is disposed between the first piezoelectric layer and the first bulk portion. The first IDT includes a first plurality of interleaved fingers. The first IDT is disposed between the first piezoelectric layer and the first substrate. One finger of the first plurality of interleaved fingers is disposed between one pillar of the first plurality of pillars and the first piezoelectric layer. One of the one or more shunt resonators includes a second iXBAR that includes a second piezoelectric layer, a second substrate including a second bulk portion and a second plurality of pillars, and a second IDT including a second plurality of interleaved fingers. The second plurality of pillars is disposed between the second piezoelectric layer and the second bulk portion. The second IDT is disposed between the second piezoelectric layer and the second substrate. One finger of the second plurality of interleaved fingers in the second IDT is disposed between one pillar of the second plurality of pillars and the second piezoelectric layer. A thickness of the pillar of the first plurality of pillars in the first iXBAR is greater than a thickness of the pillar of the second plurality of pillars in the second iXBAR.

Exemplary aspects of the disclosure include a bulk acoustic resonator such as an iXBAR and a filter including the same. In an aspect, the iXBAR includes a piezoelectric layer, a substrate, and an IDT including a plurality of interleaved fingers including a first plurality of fingers and a second plurality of fingers that are interleaved and are substantially parallel along a first axis. The IDT is disposed between the piezoelectric layer and the substrate. A pitch p that is a center-to-center spacing along a second axis between adjacent fingers of the plurality of interleaved fingers is larger than 10 times that of a thickness of the piezoelectric layer, the second axis is substantially perpendicular to the first axis, and the thickness of the piezoelectric layer is measured along an axis that is substantially perpendicular to the first and second axes.

### BRIEF DESCRIPTION OF THE DRAWINGS

The accompanying drawings, which are incorporated into and form a part of this specification, illustrate one or more example aspects of the present disclosure and, together with the detailed description, serve to explain their principles and implementations.

FIGS. 1A and 1B show a simplified schematic top view and an orthogonal cross-sectional view, respectively, of a bulk acoustic resonator device, namely an inverted transversely excited film bulk acoustic resonator (inverted XBAR or iXBAR) according to an exemplary aspect.

FIG. 2A is an expanded schematic cross-sectional view of a portion of the iXBAR of FIG. 1B.

FIG. 2B is an expanded schematic cross-sectional view of another alternative configuration of the iXBAR of FIG. 1B.

FIG. 3 is a graphic illustrating a shear acoustic mode in an iXBAR.

FIG. 4A is a schematic block diagram of a high frequency bandpass filter using iXBARs of FIGS. 1.

FIG. 4B is a schematic diagram of a radio frequency module that includes an acoustic wave filter device according to an exemplary aspect.

FIGS. 5A-5B show a perspective view and a top view of an iXBAR 500 according to an aspect of the disclosure.

FIG. 6 shows a cross-sectional view of an iXBAR 600 according to an aspect of the disclosure.

FIG. 7A is a plot that illustrates the effect of the number of pillars according to an exemplary aspect of the disclosure.

FIG. 7B is a plot that illustrates the effect of the height of the pillars 622 according to an exemplary aspect of the disclosure.

FIGS. 8-9 show effects of a pitch p that is a center-to-center spacing along between adjacent fingers of a plurality of interleaved fingers of an iXBAR according to an aspect of the disclosure.

FIG. 10A shows a perspective view of an iXBAR where a size AP of a piezoelectric layer along a first axis is equal to a distance O and a first and second plurality of fingers in the iXBAR overlap for the distance O along the first axis.

FIG. 10B shows a perspective view of an iXBAR where a size AP of a piezoelectric layer along a first axis is less than a distance O and a first and second plurality of fingers in the iXBAR overlap for the distance O along the first axis.

FIGS. 11A-11D show an effect of an extension of an overlapped region of a first and second plurality of fingers in an iXBAR with respect to a piezoelectric layer in the iXBAR along an axis that is parallel to the first and second plurality of fingers according to an aspect of the disclosure.

Throughout this description, elements appearing in figures are assigned three-digit or four-digit reference designators, where the two least significant digits are specific to the element and the one or two most significant digits are the figure number where the element is first introduced. An element that is not described in conjunction with a figure may be presumed to have the same characteristics and function as a previously described element having the same reference designator.

### DETAILED DESCRIPTION

Various aspects of the disclosed bulk acoustic resonator, a filter device, a radio frequency module, and method of manufacturing the same are now described with reference to the drawings, wherein like reference numerals are used to refer to like elements throughout. In the following description, for purposes of explanation, numerous specific details are set forth in order to promote a thorough understanding of one or more aspects of the disclosure. It may be evident in some or all instances, however, that any aspects described below can be practiced without adopting the specific design details described below. In other instances, well-known structures and devices are shown in block diagram form in order to facilitate description of one or more aspects. The following presents a simplified summary of one or more aspects of the invention in order to provide a basic understanding thereof.

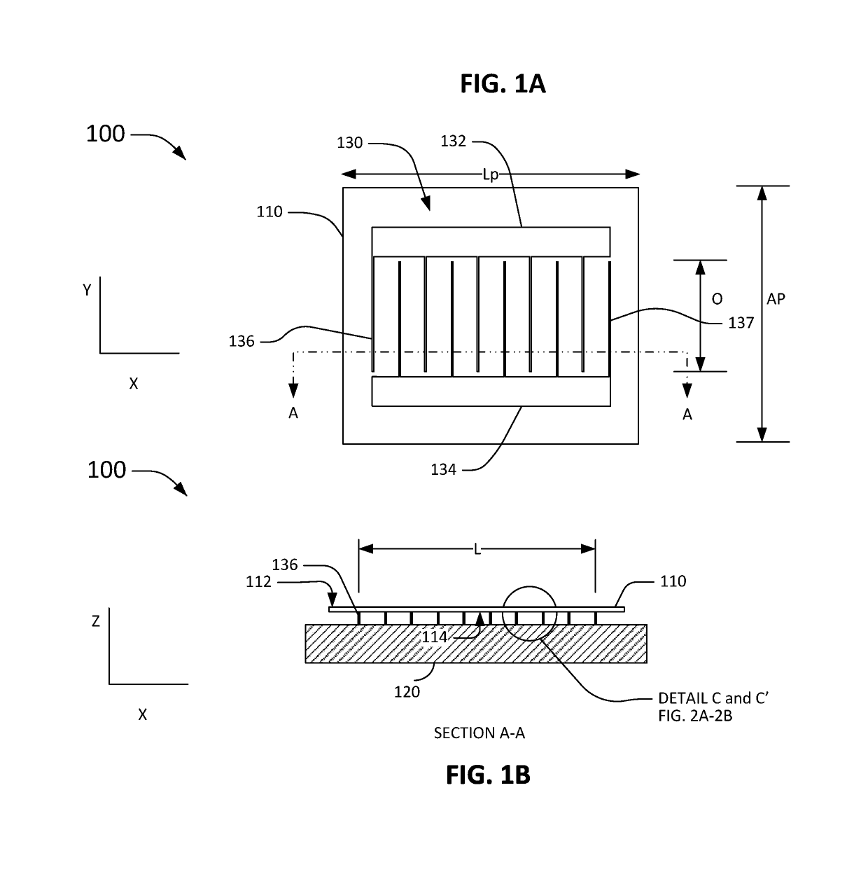

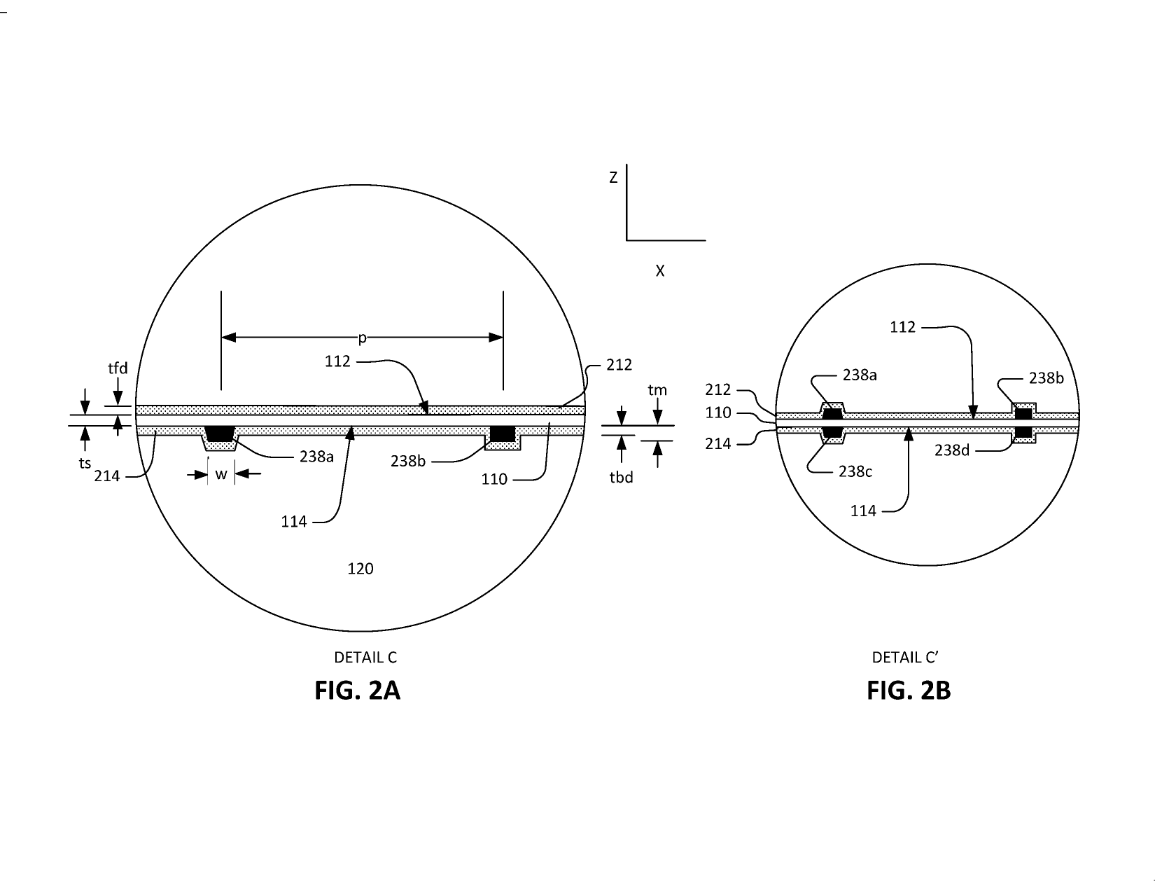

FIGS. 1A and 2B illustrate a simplified schematic top view and an orthogonal cross-sectional view, respectively, of a bulk acoustic resonator device, namely an inverted transversely excited film bulk acoustic resonator (inverted XBAR or iXBAR) 100. Inverted XBAR resonators, such as the resonator 100, may be used in a variety of RF filters including band-rejection filters, bandpass filters, duplexers, and multiplexers. Inverted XBARs are particularly suited for use in filters for communications bands with frequencies above 3 GHz.

In general, the inverted XBAR 100 includes a conductor pattern (e.g., a thin film metal layer) formed between a piezoelectric layer 110 (herein piezoelectric plate or piezoelectric layer may be used interchangeably) and a substrate 120. The piezoelectric layer 110 can have parallel front side 112 and a back side 114, respectively (also referred to generally first and second surfaces, respectively). It should be appreciated that the term “parallel” generally refers to the front side 112 and back side 114 being opposing to each other and that the surfaces are not necessarily planar and exactly parallel to each other. For example, due to the manufacturing variances result from the deposition process, the front side 112 and back side 114 may have undulations of the surface as would be appreciated to one skilled in the art. Moreover, the term “substantially” as used generally herein is used to describe when components, parameters and the like are generally the same (i.e., “substantially constant”), but may vary slightly (e.g., within an acceptable threshold or percentage) in practice due to possible manufacturing variances as would be appreciated to one skilled in the art. For purposes of this disclosure, the use of the term “or” in the claims is used to mean “and/or” unless explicitly indicated to refer to alternatives only or if the alternatives are mutually exclusive.

According to an exemplary aspect, the piezoelectric layer 110 is a thin single-crystal layer of a piezoelectric material, such as lithium niobate, lithium tantalate, lanthanum gallium silicate, gallium nitride, or aluminum nitride. It should be appreciated that the term “single-crystal” does not necessarily mean entirely of a uniform crystalline structure and may include impurities due to manufacturing variances as long as the crystal structure is within acceptable tolerances. The piezoelectric layer is cut such that the orientation of the X, Y, and Z crystalline axes with respect to the front and back sides is known and consistent. In the examples described herein, the piezoelectric layers are Z-cut, which is to say the Z axis is normal to the front and back sides 112, 114. However, inverted XBARs may be fabricated using piezoelectric layers with other crystallographic orientations including rotated Z-cut, Z-cut and rotated YX cut.

The Y-cut family, such as 120Y and 128Y, are typically referred to as 120YX or 128YX, where the “cut angle” is the angle between the y axis and the normal to the layer. The “cut angle” is equal to β+90°. For example, a layer with Euler angles [0°, 30°, 0°] is commonly referred to as “120° rotated Y-cut” or “120Y.” Thus, the Euler angles for 120YX and 128YX are (0, 120-90,0) and (0, 128-90,0) respectively. The piezoelectric layer may be, for example, a rotated Y-cut lithium niobate or a rotated Y-cut lithium tantalate, and the cut angle may be 80° to 100° or 110° to 130°. A “Z-cut” is typically referred to as a ZY cut and is understood to mean that the layer surface is normal to the Z axis but the wave travels along the Y axis. The Euler angles for ZY cut are (0, 0, 90).

The back side 114 of the piezoelectric layer 110 may be supported by the conductor pattern. The back side 114 of the piezoelectric layer 110 can be coupled or connected indirectly, via one or more intermediate layers (e.g., the conductor pattern and/or one or more dielectric layers between the conductor pattern and the substrate), to a surface of the substrate 120. Moreover, the phrase “supported by” or “attached” may, as used herein interchangeably, mean attached directly, attached indirectly, mechanically supported, structurally supported, or any combination thereof.

According to the exemplary aspect, the substrate 120 is configured to provide mechanical support to the conductor pattern and the piezoelectric layer 110. The substrate 120 may be, for example, silicon, sapphire, quartz, aluminum nitride, spinel, lithium tantalate, lithium niobate, magnesia, silicon nitride, aluminum oxide, silicon carbide, zirconia, cordierite, mullite, steatite, forsterite, diamond, glass, gallium nitride or some other material or combination of materials. In the case where the substrate 120 is silicon, the plane orientation of the surface coupled or connected either directly or indirectly, via one or more intermediate layers, to the back side 114 of the piezoelectric layer 110 may be, for example, a (100) plane, (110) plane, or (111) plane, and the resistivity may be more than or equal to 4 kW. The back side 114 of the piezoelectric layer 110 may be bonded to the substrate 120 using a wafer bonding process. Alternatively, the piezoelectric layer 110 may be grown on the substrate 120 or supported by, or attached to, the substrate in some other manner.

As shown, the conductor pattern of the inverted XBAR 100 includes an interdigital transducer (IDT) 130. The IDT 130 includes a first plurality of parallel fingers, such as fingers 136, extending from a first busbar 132 and a second plurality of fingers 137 extending from a second busbar 134. The first and second pluralities of parallel fingers are interleaved with each other that can be “substantially” parallel to each other due to minor variations, such as due to manufacturing tolerances, for example. At least a portion of the interleaved fingers overlap for a distance O along a Y axis. The center-to-center distance L along an X axis between the outermost fingers of the IDT 130 is the “length” of the IDT. A region within the X-Y surface can be formed by the overlapping of the first and second plurality of fingers 136 and 137 along the Y axis. The region within the X-Y surface has an area L×O.

In an example, when a size (or a dimension) AP of the piezoelectric layer 110 along the Y axis is larger than or equal to O, an overlap along the Y axis between the piezoelectric layer 110 and the interleaved fingers is O, and thus O is referred to as an acoustic “aperture”. For example, the distance AP may be 30 µm. In an example, when AP is less than O, the overlap along the Y axis between the piezoelectric layer 110 and the interleaved fingers is AP, and thus AP is the acoustic “aperture”. A size (or a dimension) of the piezoelectric layer 110 along the X axis is denoted as Lp, and an area of the piezoelectric layer 110 is Lp×AP.

In the example of FIG. 1B, the IDT 130 is disposed between the surface of the back side 114 (e.g., the second surface) of the piezoelectric layer 110 and the substrate 120. However, as discussed below, in other configurations, the IDT 130 may be at both the surfaces of the front and back sides 112, 114 of the piezoelectric layer 110, respectively.

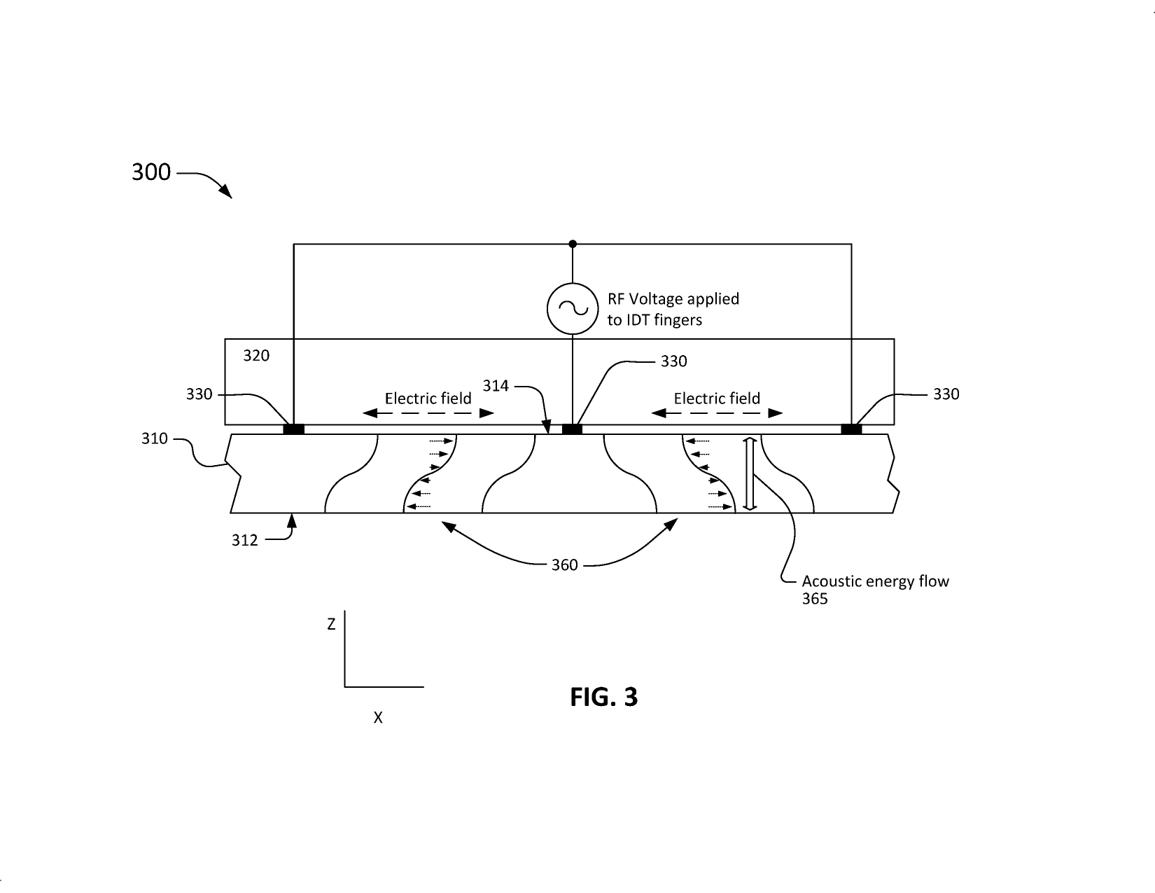

The first and second busbars 132, 134 are configured as the terminals of the inverted XBAR 100 with the plurality of interleaved fingers extending therefrom. In operation, a radio frequency signal or microwave signal applied between the two busbars 132, 134 of the IDT 130 primarily excites an acoustic mode (i.e., a primarily shear acoustic mode) within the piezoelectric layer 110. As will be discussed in further detail, the primarily excited shear acoustic mode is a bulk shear mode or bulk acoustic wave where acoustic energy of a bulk shear acoustic wave is excited in the piezoelectric layer 110 by the IDT 130 and propagates along a direction substantially, predominantly, and/or primarily orthogonal to the surface of the piezoelectric layer 110, which is also primarily normal, or transverse, to the direction of the electric field created by the IDT fingers. That is, when a radio frequency or a microwave signal is applied between the two busbars 132, 134, the RF voltage applied to the respective sets of IDT fingers generates a time-varying electric field that is laterally excited with respect to a surface of the piezoelectric layer 110. Thus, in some cases the primarily excited acoustic mode may be commonly referred to as a laterally excited bulk acoustic wave since displacement, as opposed to propagation, occurs primarily in the direction of the bulk of the piezoelectric layer, as discussed in more detail below in reference to FIG. 3.

For purposes of this disclosure, “primarily acoustic mode” may generally refer to an operational mode in which a vibration displacement is caused in the primarily thickness-shear direction (e.g., X-direction), so the wave propagates substantially and/or primarily in the direction connecting the opposing front and back surfaces of the piezoelectric layer, that is, in the Z direction. In other words, the X-direction component of the wave is significantly smaller than the Z-direction component. The use of the term “primarily” in the “primarily excited acoustic mode” is not necessarily referring to a lower or higher order mode. Thus, the inverted XBAR is considered a transversely-excited film bulk wave resonator. One physical constraint is that when the radio frequency or microwave signal is applied between the two busbars 132, 134 of the IDT 130, heat is generated that must be dissipated from the resonator for improved performance. In general, heat can be dissipated through the substrate 120 vertically, for example, through vertical conduction via the IDT 130. Heat can also be dissipated by lateral conduction, e.g., in the electrodes themselves. Comparing an iXBAR and an XBAR where a piezoelectric layer is disposed between an IDT and a substrate, the iXBAR has better heat dissipation and thus better power handling capability because the IDT in the iXBAR directly contacts the substrate, and thus heat dissipation in the iXBAR can move through the substrate more quickly, which is unlike the XBAR where heat dissipation is primarily via the lateral conduction. Another benefit of the iXBAR is that the iXBAR has a high reflectivity from the vacuum without using a Bragg mirror such as used in a solidly mounted XBAR or SM-XBAR. In addition, an iXBAR may have good mechanical stability, and robustness as compared to an XBAR.

According to an exemplary aspect, when L is equal to Lp and the size AP of the piezoelectric layer 110 along the Y axis is larger than or equal to O, the area of inverted XBAR 100 is determined as the area of the IDT 130. For example, the area of the IDT 130 can be determined based on the measurement of the length L multiplied by the width of the aperture O of the interleaved fingers of the IDT 130 (i.e., L×O). When L is equal to Lp and AP is less than O, the area of inverted XBAR 100 is determined as the area of the piezoelectric layer 110. For example, the area of the piezoelectric layer 110 can be determined based on the measurement of the length L multiplied by AP (i.e., L×AP). As used herein through the disclosure, area is referenced in µm². Thus, the area of the inverted XBAR 100 may be adjusted based on design choices, as described below, thereby adjusting the overall capacitance of the inverted XBAR 100.

For ease of presentation in FIG. 1A, the geometric pitch and width of the IDT fingers is greatly exaggerated with respect to the length (dimension L, Lp) and aperture (dimension AP or O) of the inverted XBAR. A typical iXBAR has more than ten parallel fingers in the IDT. For example, an inverted XBAR may have hundreds, possibly thousands, of parallel fingers in the IDT according to exemplary aspects. Similarly, the thickness of the fingers in the cross-sectional views is greatly exaggerated.

Openings and may be provided in the piezoelectric layer. The openings are through holes penetrating the piezoelectric layer 110. The openings may have a rectangular shape in plan view and be provided along edges of the openings extending in a direction that the plurality of interleaved fingers extend. Any suitable shape, number and/or position of the openings may be adjusted based on design choices.

FIG. 2A shows a detailed schematic cross-sectional view (labeled as Detail C) of the inverted XBAR 100 of FIG. 1B. In this exemplary aspect, the piezoelectric layer 110 can be a single-crystal layer of piezoelectrical material having a thickness ts. Ts may be, for example, 100 nanometers (nm) to 1500 nm. When used in filters for 5G NR and Wi-Fi^{TM} bands from 3.4 GHZ to 7 GHz, the thickness ts may be, for example, 150 nm to 500 nm. The thickness ts can be measured in a direction (e.g., the Z axis) substantially perpendicular or orthogonal to a surface of the piezoelectric layer in an exemplary aspect. In the case that the thickness of the piezoelectric layer 110 has variances, the thickness ts may be the average value.

In this aspect, a front side dielectric layer 212 (e.g., a first dielectric coating layer or material) can be formed on the front side 112 of the piezoelectric layer 110. The “front side” of the inverted XBAR is, by definition, the surface facing away from the substrate. The front side dielectric layer 212 has a thickness tfd. In some examples (not shown), there is no front side dielectric layer 212.

A back side dielectric layer 214 (e.g., a second dielectric coating layer or material) can also be formed on the back side 114 of the piezoelectric layer 110. In general, for purposes of this disclosure, the term “back side” means on a side opposite the front side dielectric layer 212. Moreover, the back side dielectric layer 214 has a thickness tbd. As shown in FIG. 2A the back side dielectric layer 214 covers the IDT fingers 238a, 238b, which can correspond to the fingers 136 and/or 137 as described above with respect to FIGS. 1A and 1B. Although not shown in FIG. 2A, the back side dielectric layer 214 may also be deposited only between the IDT fingers 238a, 238b. In this case, an additional thin dielectric layer (not shown) may be deposited between the IDT fingers and the substrate 120 to seal and passivate the fingers. In another example, the back side dielectric layer 214 may be deposited only between the IDT fingers 238a, 238b, and no dielectric layer is disposed between the IDT fingers and the substrate 120. Further, although also not shown in FIG. 2A, the back side dielectric layer 214 may also be deposited only on select IDT fingers 238a, for example. In some examples (not shown), there is no back side dielectric layer 214.

The front side and back side dielectric layers 212, 214 may be a non-piezoelectric dielectric material, such as silicon oxide, silicon dioxide, aluminum nitride, aluminum oxide, tantalum oxide, niobium oxide or silicon nitride. Tfd and tbd may be, for example, 0 to 500 nm. Tfd and tbd may be less than the thickness ts of the piezoelectric layer. Tfd and tbd are not necessarily equal, and the front side and back side dielectric layers 212, 214 are not necessarily the same material. In exemplary aspect, either or both of the front side and back side dielectric layers 212, 214 may be formed of multiple layers of two or more materials according to various exemplary aspects.

The IDT fingers 238a, 238b may comprise aluminum, substantially (i.e., predominantly) aluminum alloys, copper, substantially (i.e., predominantly) copper alloys, beryllium, gold, molybdenum, or some other conductive material. Thin (relative to the total thickness of the conductors) layers of other metals, such as chromium or titanium, may be formed under and/or over the fingers to improve adhesion between the fingers and the piezoelectric layer 110 and/or to passivate or encapsulate the fingers. The busbars (132, 134 in FIG. 1A) of the IDT may be made of the same or different materials as the fingers. The cross-sectional shape of the IDT fingers may be trapezoidal (finger 238a), rectangular (finger 238b) or some other shape in various exemplary aspects. In general, it is noted that the terms “comprise”, “have”, “include” and “contain” (and their variants) as used herein are open-ended linking verbs and allow the addition of other elements when used in a claim. Moreover, the use of the word “a” or “an” when used in conjunction with the term “comprising” in the claims or the specification means one or more than one, unless the context dictates otherwise.

Dimension p (i.e., the “pitch”) can be considered the center-to-center spacing between adjacent IDT fingers, such as the IDT fingers 238a, 238b in FIGS. 2A-2B. Center points of center-to-center spacing may be measured at a center of the width “w” of a finger as shown in FIG. 2A. In some cases, the center-to-center spacing may change if the width of a given finger changes along the length of the finger, if the width and extending direction changes, or any variation thereof. In that case, for a given location along O, center-to-center spacing may be measured as an average center-to-center spacing, a maximum center-to-center spacing, a minimum center-to-center spacing, or any variation thereof. Adjacent fingers may each extend from a different busbar and center-to-center spacing may be measured from a center of a first finger extending from a first busbar to a center of a second finger, adjacent to the first finger, extending from a second busbar. The center-to-center spacing may be constant over the length of the IDT, in which case the dimension p may be referred to as the pitch of the IDT and/or the pitch of the inverted XBAR. However, in an alternative exemplary aspect, the center-to-center spacing varies along the length of the IDT, in which case the pitch of the IDT may be the average value of dimension p over the length of the IDT. The pitch p may be, for example, 1 microns (µm) to 10 µm. Center-to-center spacing from one finger to an adjacent finger may vary continuously when compared to other adjacent fingers, in discrete sections of multiple adjacent pairs, or any combination thereof. Each IDT finger, such as the IDT fingers 238a, 238b in FIGS. 2A-2B, has a width w measured normal to the long direction of each finger. The width w may also be referred to herein as the “mark.” In general, the width of the IDT fingers may be constant over the length of the IDT, in which case the dimension w may be the width of each IDT finger. However, in another exemplary aspect as will be discussed below, the width of individual IDT fingers varies along the length of the IDT 130, in which case dimension w may be the average value of the widths of the IDT fingers over the length of the IDT. Note that the pitch p and the width w of the IDT fingers are measured in a direction (e.g., the X axis) substantially parallel to the length L of the IDT, as defined in FIG. 1A.

In general, the IDT of an inverted XBAR differs substantially from the IDTs used in surface acoustic wave (SAW) resonators, primarily in that IDTs of an inverted XBAR excite a shear acoustic mode (also referred to as a primary shear mode, a primary shear thickness mode, or the like), as described in more detail below with respect to FIG. 3, where SAW resonators excite a surface wave in operation. For example, the wave mode may be a zeroth order mode, a first order mode, a secondary mode, a tertiary mode or higher order modes. Moreover, in a SAW resonator, the pitch of the IDT is one-half of the acoustic wavelength at the resonance frequency. Additionally, the mark-to-pitch ratio of a SAW resonator IDT is typically close to 0.5 (i.e., the mark or finger width is about one-fourth of the acoustic wavelength at resonance). In an inverted XBAR, the pitch p of the IDT is typically 2 to 20 times the width w of the fingers. In addition, the pitch p of the IDT is typically 2 to 20 times the thickness ts of the piezoelectric layer 110. According to an aspect of the disclosure, the pitch p of the IDT in an iXBAR is larger than 10 times the thickness ts of the piezoelectric layer 110. Moreover, the width of the IDT fingers in an inverted XBAR is not constrained to one-fourth of the acoustic wavelength at resonance. For example, the width of inverted XBAR IDT fingers may be 500 nm or greater, such that the IDT can be fabricated using optical lithography. The thickness tm of the IDT fingers may be from 100 nm to about equal to the width w, as the lithography process typically cannot support a configuration where the thickness is greater than the width. The thickness of the busbars (132, 134 in FIG. 1A) of the IDT may be the same as, less than, greater than, or any combination thereof, the thickness tm of the IDT fingers. It is noted that the inverted XBAR devices described herein are not limited to the ranges of dimensions described herein.

Moreover, unlike a SAW filter, the resonance frequency of an inverted XBAR is dependent on the total thickness (i.e., in the vertical or thickness direction), including the piezoelectric layer 110, and the front side and back side dielectric layers 212, 214 disposed thereon. In an exemplary aspect, the thickness of one or both dielectric layers can (i.e., on the opposing surfaces of the piezoelectric layer) be varied to change the resonance frequencies of various inverted XBARs in a filter. For example, shunt resonators in a ladder filter circuit may incorporate thicker dielectric layers to reduce the resonance frequencies of the shunt resonators relative to series resonators with thinner dielectric layers, and thus a thinner overall thickness.

Referring back to FIG. 2A, the thickness tbd of the back side dielectric layer 214 over the IDT fingers 238a, 238b may be greater than or equal to a minimum thickness required to cover and passivate the IDT fingers and other conductors on the back side 114 to the piezoelectric layer 110. The minimum thickness may be, for example, 10 nm to 50 nm depending on the material of the back side dielectric layer and method of deposition according to an exemplary aspect. The thickness of the front side dielectric layer 212 may be configured to a specific thickness to adjust the resonance frequency of the resonator as described in more detail below.

Although FIG. 2A discloses a configuration in which IDT fingers 238a and 238b are at the back side 114 of the piezoelectric layer 110, alternative configurations can be provided.

FIG. 2B shows an alternative configuration (identified as Detail C’) in which IDT fingers 238a, 238b are on the front side 112 of the piezoelectric layer 110 and are covered by a front side dielectric layer 212. IDT fingers 238c, 238d are on the back side 114 of the piezoelectric layer 110 and are covered by a back side dielectric layer 214. As previously described, the front side and back side dielectric layer 212, 214 are not necessarily the same thickness or the same material.

FIG. 3 is a graphical illustration of the primarily excited acoustic mode (also referred to as a primary acoustic mode) of interest in an inverted XBAR. FIG. 3 shows a small portion of an inverted XBAR 300 including a piezoelectric layer 310 and three interleaved IDT fingers 330. The IDT fingers 330 are disposed between the piezoelectric layer 310 and a substrate 320, for example, between a back side 314 of the piezoelectric layer 310 and the substrate 320. The back side 314 of the piezoelectric layer 310 opposes a front side 312 of the piezoelectric layer 310. In general, the exemplary configuration of inverted XBAR 300 can correspond to any of the configurations described above and shown in FIGS. 2A-2B according to an exemplary aspect. Thus, it should be appreciated that the piezoelectric layer 310 can correspond to the piezoelectric layer 110, the substrate 320 can correspond to the substrate 120 in FIG. 1B, and IDT fingers 330 can be implemented according to any of the configurations of fingers 238a and 238b, for example.

In operation, an RF voltage is applied to the interleaved fingers 330. This voltage creates a time-varying electric field between the fingers. The direction of the electric field is lateral (i.e., laterally excited), or primarily parallel to the surface of the piezoelectric layer 310, as indicated by the arrows labeled “electric field.” In an example, the direction of the electric field is orthogonal to the length of the IDT fingers. Due to the high dielectric constant of the piezoelectric layer 310, the electric field is highly concentrated in the piezoelectric layer relative to the air. The lateral electric field introduces shear deformation in the piezoelectric layer 310, and thus strongly excites a shear acoustic mode, in the piezoelectric layer 310. In this context, “shear deformation” is defined as deformation in which parallel planes in a material remain parallel and maintain a constant distance while translating relative to each other. In other words, the parallel planes of material are laterally displaced with respect to each other. A “shear acoustic mode” is defined as an acoustic vibration mode in a medium that results in shear deformation of the medium. The shear deformations in the inverted XBAR 300 are represented by curves 360, with the adjacent small arrows providing a schematic indication of the direction and magnitude of atomic motion. It is noted that the degree of atomic motion, as well as the thickness of the piezoelectric layer 310, have been exaggerated for ease of visualization in FIG. 3. While the atomic motions are predominantly lateral (i.e., horizontal as shown in FIG. 3), the direction of acoustic energy flow of the primarily excited shear acoustic mode is substantially and/or primarily orthogonal to the surface of the piezoelectric layer, as indicated by an arrow 365. Thus, even if the number of pairs of the IDT fingers 330 is reduced to miniaturize the XBAR 300, the Q factor is less likely to be decreased in many cases. Additionally, the XBAR 300 does not require reflectors sandwiching the IDT fingers 330 in the lateral direction.

In various examples, a bulk acoustic resonator based on shear acoustic wave resonances can achieve better performance than current state-of-the art film-bulk-acoustic-resonators (FBAR) and solidly-mounted-resonator bulk-acoustic-wave (SMR BAW) devices where the electric field is applied in the thickness direction. In such devices, the acoustic mode is compressive with atomic motions and the direction of acoustic energy flow in the thickness direction. In addition, the piezoelectric coupling for shear wave inverted XBAR resonances can be high (>20%) compared to other acoustic resonators. Thus, high piezoelectric coupling enables the design and implementation of microwave and millimeter-wave filters with appreciable bandwidth.

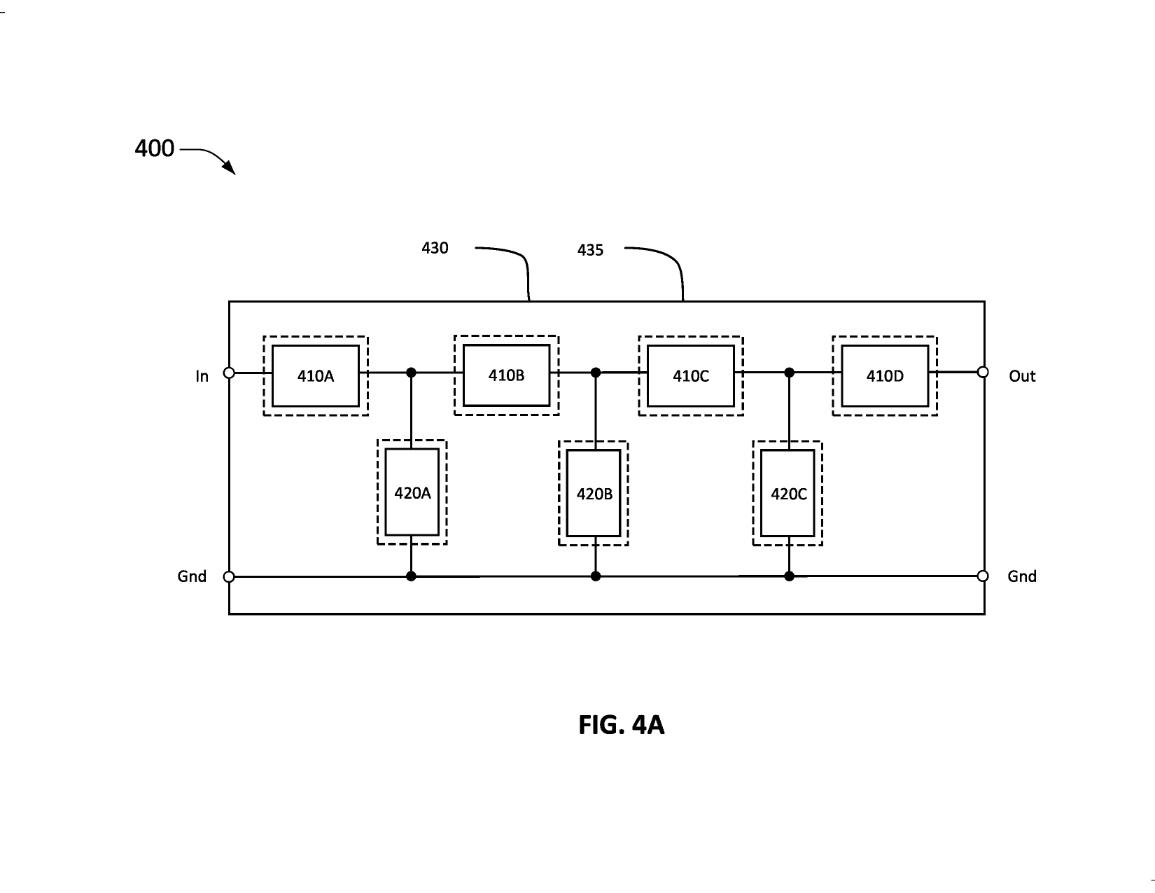

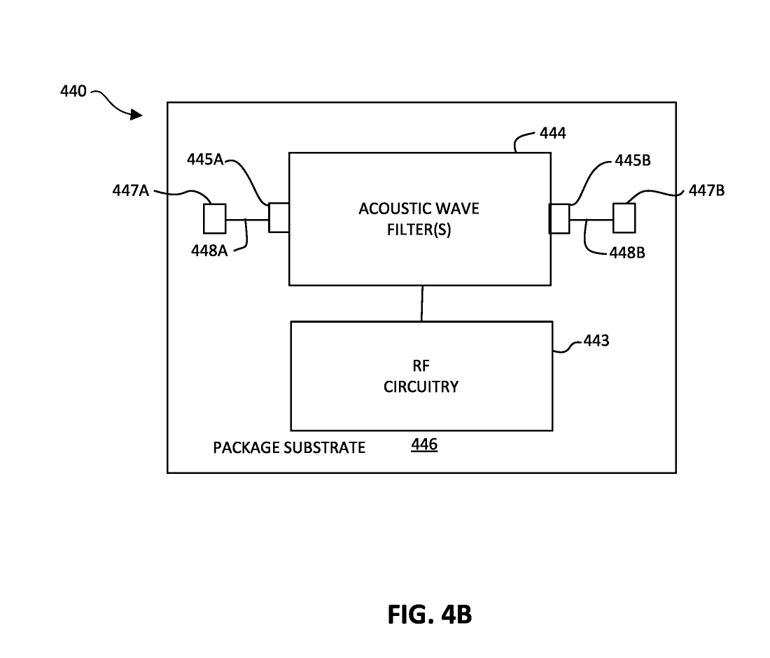

FIG. 4A is a schematic circuit diagram and layout for a high frequency bandpass filter 400 using XBARs, such as the general inverted XBAR configuration 100 (e.g., the bulk acoustic resonators) described above, for example. The filter 400 has a conventional ladder filter architecture, which may include a split-ladder filter architecture wherein the filter is split between multiple chips, which has a plurality of bulk acoustic resonators including four series resonators 410A, 410B, 410C, and 410D and three shunt resonators 420A, 420B and 420C. The series resonators 410A, 410B, 410C and 410D are connected in series between a first port and a second port (hence the term “series resonator”). In FIG. 4A, the first and second ports are labeled “In” and “Out”, respectively. However, the filter 400 is bidirectional and either port may serve as the input or output of the filter. At least two shunt resonators, such as the shunt resonators 420A and 420B, are connected from nodes between series resonators to a ground connection. A filter may contain additional reactive components, such as inductors, not shown in FIG. 4A. Divided resonators may be referred to as “sub-resonators” wherein two or more sub-resonators are resonators having an aperture and length that are substantially similar to each other. This may be done to target the same frequency while reducing the static capacitance of a resonator that would otherwise be larger if not divided into two or more sub-resonators. In some cases, a pitch, or average pitch, of two or more sub-resonators may be same as well, while in some cases slight variations of pitch or average pitch may exist between divided sub-resonators. All the shunt resonators and series resonators are iXBARs (e.g., the iXBAR configuration 100 as discussed above) in the exemplary aspect. The inclusion of three series and two shunt resonators is an example. A filter may have more or fewer than five total resonators, more or fewer than three series resonators, and more or fewer than two shunt resonators. Typically, for a split ladder and non-split-ladder filter architectures, all of the series resonators are connected in series between an input and an output of the filter, and all of the shunt resonators are typically connected between ground and the input, the output, or a node between two series resonators.

In the exemplary filter 400, the series resonators 410A, 410B, 410C and 410D and the shunt resonators 420A, 420B and 420C of the filter 400 can be formed on a silicon substrate (not visible) using at least one, and in some cases a single, piezoelectric layer 430 of piezoelectric material (not visible). However, in alternative aspects, the individual resonators may each be formed on a separate respective piezoelectric layer for each resonator wherein all resonators are located on the same chip. In some cases, however, different resonators of a filter may be bonded to a separate substrate, for example. This may result in a split-ladder architecture that can include one or a plurality of separate chips that include separate piezoelectric layers and IDTs of one or more bulk acoustic resonators that are then configured together to form the overall split ladder filter. Moreover, each resonator includes a respective IDT (not shown), with at least the fingers of the IDT disposed between the substrate and the piezoelectric layer. In this and similar contexts, the term “respective” means “relating things each to each,” which is to say with a one-to-one correspondence. In FIG. 4A, the cavities are illustrated schematically as the dashed rectangles (such as the rectangle 435). In this example, each IDT is disposed between the substrate and the piezoelectric layer. In other filters, the IDTs of two or more resonators may be disposed between the substrate and the piezoelectric layer.

Each of the resonators 410A, 410B, 410C, 410D, 420A, 420B and 420C in the filter 400 has a resonance where the admittance (also interchangeably referred to as Y-parameter) of the resonator is very high and an anti-resonance where the admittance of the resonator is very low. The resonance and anti-resonance occur at a resonance frequency and an anti-resonance frequency, respectively, which may be the same or different for the various resonators in the filter 400. In simplified terms, each resonator can be considered a short-circuit at its resonance frequency and an open circuit at its anti-resonance frequency. The input-output transfer function will be near zero at the resonance frequencies of the shunt resonators and at the anti-resonance frequencies of the series resonators. In a typical filter, the resonance frequencies of the shunt resonators are positioned below the lower edge of the filter’s passband and the anti-resonance frequencies of the series resonators are positioned above the upper edge of the passband.

The frequency range between resonance and anti-resonance frequencies of a resonator corresponds to the coupling of the resonator. Depending on the design parameters of the filter 400, each of the resonators 410A, 410B, 410C, 410D, 420A, 420B and 420C may have a particular coupling parameter to which the respective resonator is tuned in order to achieve the required frequency response of the filter 400.

According to an exemplary aspect, each of the series resonators 410A, 410B, 410C and 410D and the shunt resonators 420A, 420B and 420C can have an iXBAR configuration as described above with respect to FIGS. 1-2B.

FIG. 4B is a schematic diagram of a radio frequency module that includes an acoustic wave filter device according to an exemplary aspect. In particular, FIG. 4B illustrates a radio frequency module 440 that includes one or more acoustic wave filters 444 according to an exemplary aspect. The illustrated radio frequency module 440 also includes radio frequency (RF) circuitry (or RF circuit) 443. In an exemplary aspect, the acoustic wave filters 444 may include one or more of filter 400 including inverted XBARs (e.g., the bulk acoustic resonators described herein), as described above with respect to FIG. 4A.

The acoustic wave filter 444 shown in FIG. 4B includes terminals 445A and 445B (e.g., first and second terminals). The terminals 445A and 445B can serve, for example, as an input contact and an output contact for the acoustic wave filter 444. Although two terminals are illustrated, any suitable number of terminals can be implemented for a particular application. The acoustic wave filter 444 and the RF circuitry 443 are on a package substrate 446 (e.g., a common substrate) in FIG. 4B. The package substrate 446 can be a laminate substrate. The terminals 445A and 445B can be electrically connected to contacts 447A and 447B, respectively, on the package substrate 446 by way of electrical connectors 448A and 448B, respectively. The electrical connectors 448A and 448B can be bumps or wire bonds, for example. In an exemplary aspect, the acoustic wave filter 444 and the RF circuitry 443 may be enclosed together within a common package, with or without using the package substrate 446.

The RF circuitry 443 can include any suitable RF circuitry. For example, the RF circuitry can include one or more radio frequency amplifiers (e.g., one or more power amplifiers and/or one or more low noise amplifiers), one or more radio frequency switches, one or more additional RF filters, one or more RF couplers, one or more delay lines, one or more phase shifters, or any suitable combination thereof. The RF circuitry 443 can be electrically connected to the one or more acoustic wave filters 444. The radio frequency module 440 can include one or more packaging structures to, for example, provide protection and/or facilitate easier handling of the radio frequency module 440. Such a packaging structure can include an overmold structure formed over the package substrate 446. The overmold structure can encapsulate some or all of the components of the radio frequency module 440.

According to an aspect of the disclosure, an inverted XBAR (or iXBAR) can include a piezoelectric layer, a substrate, and an IDT disposed between the piezoelectric layer and the substrate. Referring back to FIGS. 1A and 1B, the inverted XBAR or the iXBAR 100 includes the piezoelectric layer 110, the substrate 120, and the IDT 130 disposed between the piezoelectric layer 110 and the substrate 120. The IDT 130 can include a plurality of interleaved fingers including the first plurality of fingers 136 and the second plurality of fingers 137 that are interleaved. In an example, the plurality of interleaved fingers is parallel (or substantially parallel) along a first axis (e.g., the Y axis), and the first and second plurality of fingers 136 and 137 overlap for the distance (also referred to an overlapped size) O along the first axis.

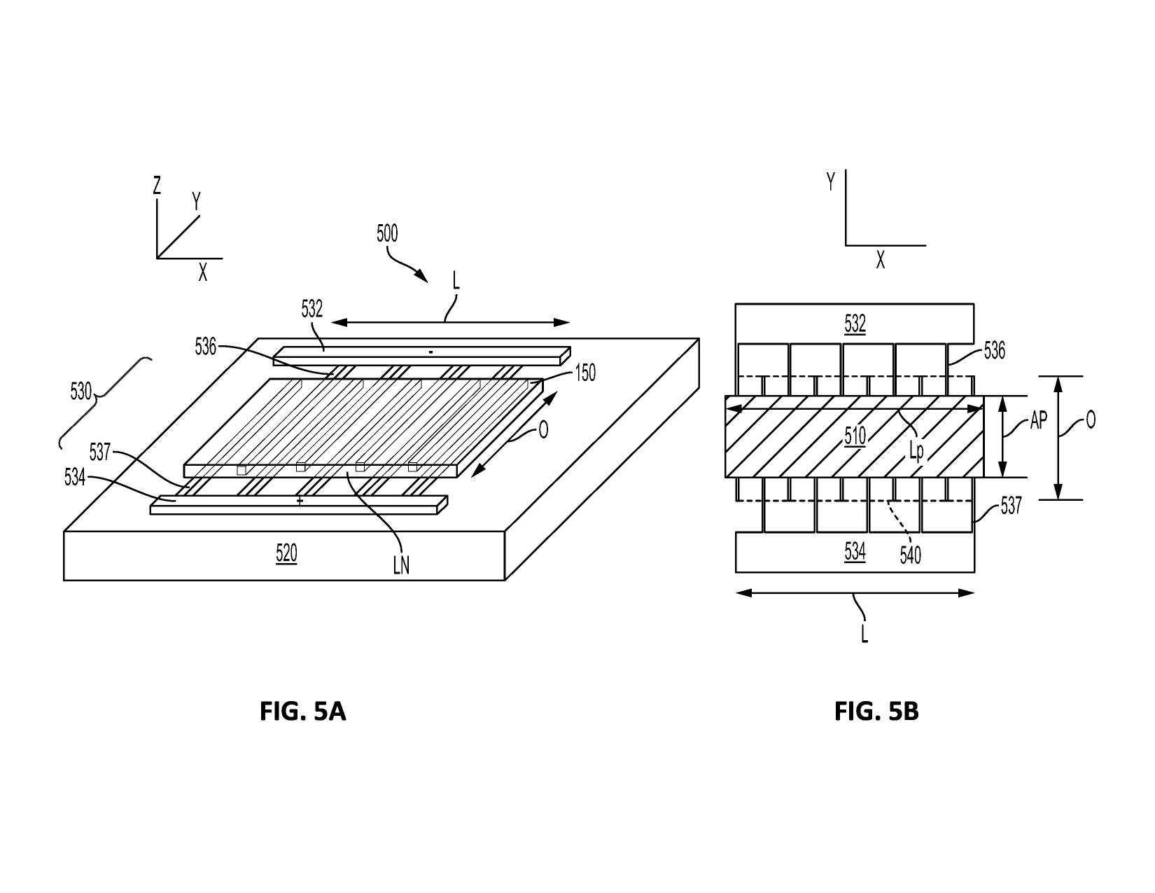

In the example shown in FIG. 1A, the overlapped size O of the first and second plurality of fingers 136 and 137 is less than the size AP of the piezoelectric layer 110 along the Y axis. According to another aspect of the disclosure, the size AP of the piezoelectric layer along the first axis (e.g., the Y axis) can be less than or equal to the distance O, as shown in FIG. 5B.

FIGS. 5A-5B show a perspective view and a top view of an iXBAR 500 according to an aspect of the disclosure. The iXBAR 500 can include a piezoelectric layer 510, a substrate 520, and an IDT 530 disposed between the piezoelectric layer 510 and the substrate 520. The IDT 530 can include a plurality of interleaved fingers including a first plurality of fingers 536 and a second plurality of fingers 537 that are interleaved with each other. In an example, the plurality of interleaved fingers is parallel along a first axis (e.g., the Y axis), and the first and second plurality of fingers 536 and 537 overlap for the distance (also referred to an overlapped size) O along the first axis (e.g., the Y axis). The first plurality of fingers 536 can extend from a first busbar 532 and a second plurality of fingers 537 can extend from a second busbar 534. When a radio frequency or a microwave signal is applied between the two busbars 532, 534, the RF voltage applied to the respective sets of IDT fingers generates a time-varying electric field that is laterally excited with respect to a surface of the piezoelectric layer 510. The iXBAR 500 can be a variation of the iXBAR 100. In an example, the iXBAR 500 is similar to the iXBAR 100 except that the size AP of the piezoelectric layer 510 along the first axis (e.g., the Y axis) can be less than or equal to the distance or the overlapped size O. For purposes of this disclosure, it is noted that components labeled as 5xx in the iXBAR 500 where xx is between 10 to 37 can be similar or identical to components labeled as 1xx in the iXBAR 100, and thus descriptions for the components labeled as 1xx in the iXBAR 100 can be applied to or suitably adapted for components labeled as 5xx in the iXBAR 500.

Referring to FIG. 5B, in an example, a size of the piezoelectric layer 510 along the second axis (e.g., the X axis) is Lp along the second axis. An area of the piezoelectric layer 510 in a surface (e.g., an X-Y surface) parallel to the X and Y axes is Lp×AP.

A distance L refers to a center-to-center distance between outermost fingers of the plurality of interleaved fingers in the IDT 530 along the second axis. In an example, a region 540 within the X-Y surface is formed by the overlapping of the first and second plurality of fingers 536 and 537 along the Y axis, and the region 540 has the size L along the X axis. The region 540 within the X-Y surface has an area L×O.

In an example, AP is less than O, and thus the piezoelectric layer 510 is disposed within the region 540 along the Y axis.

In an example, AP is equal to O, and thus the piezoelectric layer 510 overlaps with the region 540 along the Y axis.

In an example, Lp is equal to L, and thus the piezoelectric layer 510 overlaps with the region 540 along the X axis.

In an example, Lp is larger or less than L.

In an example, Lp is equal to L, and thus AP is less than or equal to O. Thus, the piezoelectric layer 510 is disposed within the region 540, and Lp×AP is less than or equal to L×O.

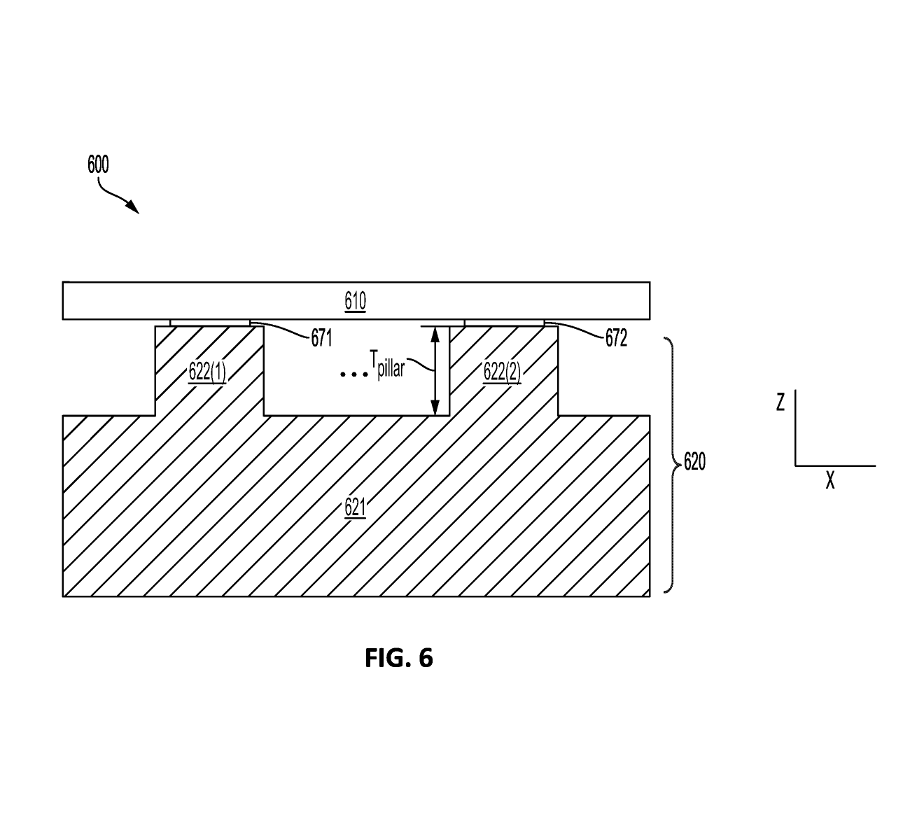

In an exemplary aspect, a substrate in an iXBAR can include a bulk portion (also referred to as a base portion) and a plurality of pillars. The plurality of pillars can be disposed between the piezoelectric layer and the bulk portion. One finger of the plurality of interleaved fingers can be disposed between one pillar of the plurality of pillars and the piezoelectric layer. FIG. 6 shows a cross-sectional view of an iXBAR 600 according to an aspect of the disclosure. The iXBAR 600 can be a variation to the iXBAR 100 or 500. Similar to the iXBAR 100 or 500, the iXBAR 500 can include a piezoelectric layer 610, a substrate 620, and an IDT disposed between the piezoelectric layer 610 and the substrate 620. The IDT can include a plurality of interleaved fingers including a first plurality of fingers and a second plurality of fingers that are interleaved with each other.

In an example, the iXBAR 600 is similar to the iXBAR 100 or 500 except that the substrate 620 includes a bulk portion 621 and a plurality of pillars 622 including pillars 622(1)-622(2) shown in FIG. 6. The plurality of pillars 622 can be disposed between the piezoelectric layer 610 and the bulk portion 621. The plurality of fingers 622 can be integrally formed with the bulk (i.e., base) portion 621 or can be formed as a separate component deposited thereon.

As further shown, in the exemplary aspect, a finger 671 of the plurality of interleaved fingers in the IDT can be disposed between the pillar 622(1) of the plurality of pillars 622 and the piezoelectric layer 610. Similarly, a finger 672 of the plurality of interleaved fingers in the IDT can be disposed between the pillar 622(2) of the plurality of pillars 622 and the piezoelectric layer 610. Thus, in an exemplary aspect, the fingers are disposed directly between the bottom surface of the piezoelectric layer 610 and a top surface of each of the plurality of pillars 622. In other aspects, one or more additional layers (e.g., an adhesion layer and/or an oxide layer) may be disposed therebetween (e.g., between the piezoelectric layer 610 and the fingers 671/672 and/or between the pillar 622 and the fingers 671/672) as long as a continuous mechanical coupling is provided between the plurality of pillars 622 of the substrate 620 and the piezoelectric layer 610.

The plurality of pillars 622 can have any suitable shape, material(s), and can be fabricated using any suitable process. The shape including a height of the plurality of pillars 622, the material, and/or the like of the plurality of pillars 622, can be selected based on requirements of the iXBAR 600 and the applications. The shape of a pillar of the plurality of pillars 622 within the X-Y plane can be polygonal, circular, oval, or any suitable shape. The material of the plurality of pillars 622 can be identical to (e.g., integrally formed) or different from the material of the bulk portion 621. The materials of the plurality of pillars 622 and the bulk portion 621 can include one or more materials such as dielectric materials described for the substrate 120. The plurality of pillars 622 can be deposited onto the bulk portion 621 using any suitable deposition process. The plurality of pillars 622 can be formed by etching the bulk portion 621 using any suitable etching process or a combination of depositions and etching processes.

In an exemplary aspect, including a plurality of pillars (e.g., 622) in an iXBAR (e.g., 600) can be beneficial. Without pillars, there can be a large coupling penalty, for example, due to an electric field leaking from a piezoelectric layer (e.g., 610) into a substrate (e.g., 620 or the bulk portion 621) of the iXBAR. With the plurality of pillars 622, the bulk portion 621 of the substrate 620 is separated from the piezoelectric layer 610 using the plurality of pillars 622, which can mitigate the coupling loss. In an aspect, increasing a height (or a thickness) Tₚᵢₗₗₐᵣ of the plurality of pillars 622 that is measured along the Z axis can increase the separation between the piezoelectric layer 610 and the bulk portion 621, and thus reducing coupling loss. However, increasing the height Tₚᵢₗₗₐᵣ of the plurality of pillars 622 can also reduce heat dissipation, which may not be beneficial for power handling capability. Thus, the height Tₚᵢₗₗₐᵣ of the plurality of pillars 622 can be determined based on the requirements of the iXBAR 600, such as the coupling, power handling capability, and/or the like.

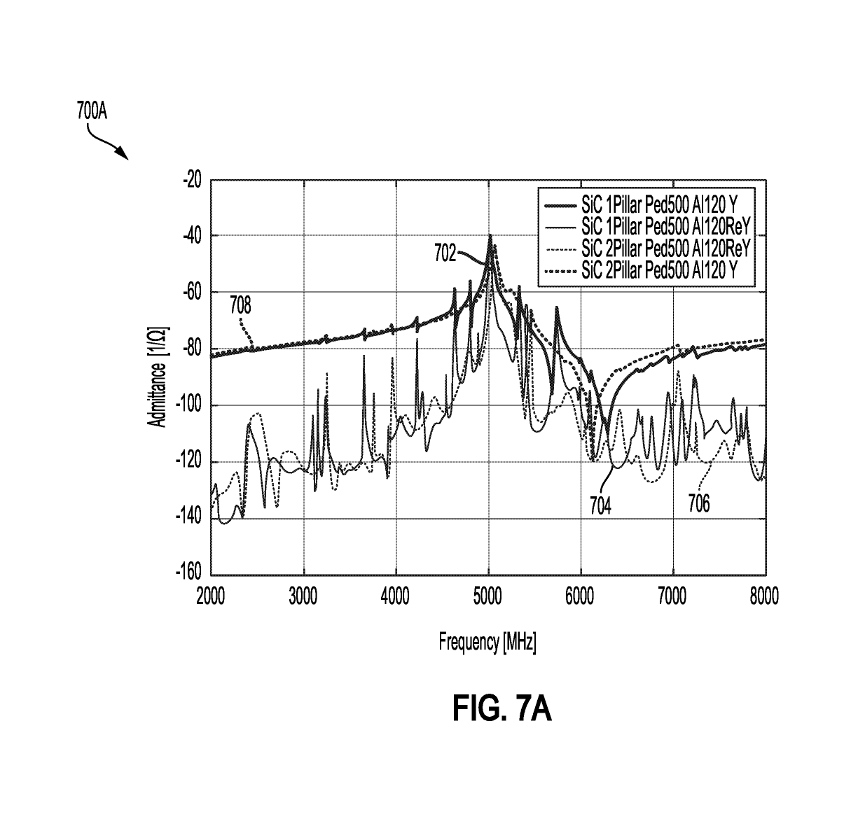

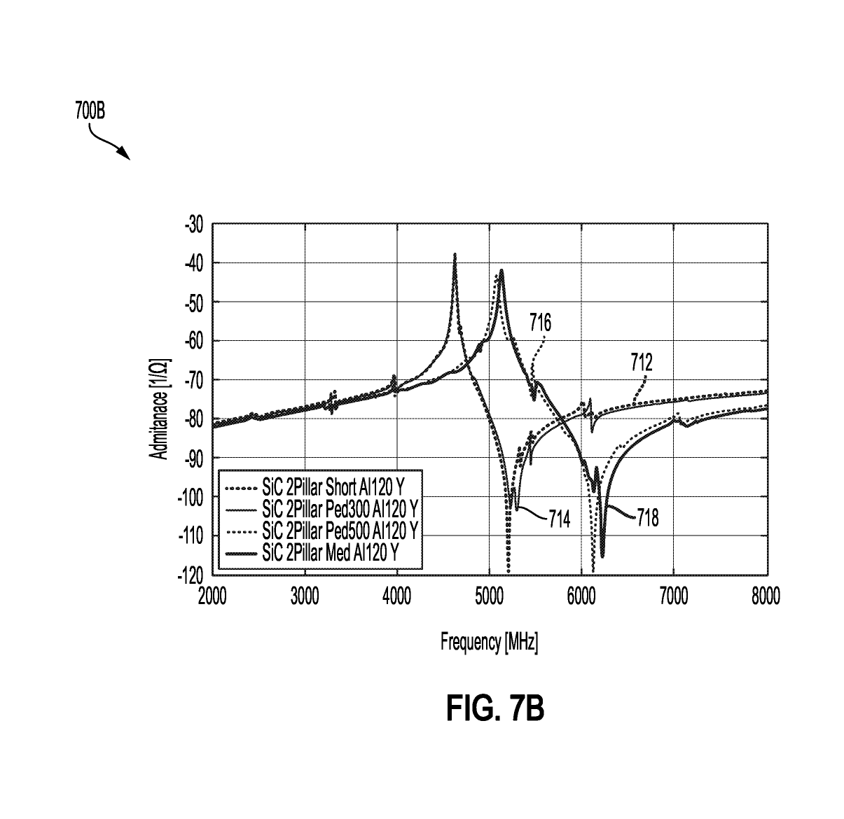

FIG. 7A is a plot 700A that illustrates the effect of the number of pillars 622 according to an exemplary aspect of the disclosure. FIG. 7B is a plot 700B that illustrates the effect of the height of the pillars 622 according to an exemplary aspect of the disclosure. In general, the plots shown in FIGS. 7A and 7B, as well as those discussed below, are simulated using finite element method (FEM) simulation techniques.

Referring first to FIG. 7A, the graphs show simulated admittance (a Y-parameter in admittance 1/Ω) curves of the iXBAR 600 versus a frequency in unit of Megahertz (MHz). The frequency range is from 2000 to 8000 MHz. Both the absolute values ΙYΙ of the Y-parameters and the real components Re(Y) of the Y-parameters are plotted. That is, plot 702 illustrates admittance Y for a single (N = 1) pillar configuration (discussed below) at 500 nanometers (nm) and the plot 708 illustrates admittance Y for a double (N = 2) pillar configuration (also discussed below) also at 500 nm. Similarly, plot 704 illustrates the real admittance Re(Y) for the single pillar configuration at 500 nanometers (nm) and the plot 706 illustrates the real admittance Re(Y) for the double pillar configuration also at 500 nm. In the iXBAR structure 600 used in the simulations for the plots in FIG. 7A, the IDT fingers 671 and/or 672 are aluminum and the substrate 620 includes SiC.

Moreover, in the iXBAR structure 600 used in the simulation for the plots in FIG. 7A, each finger of the plurality of interleaved fingers is disposed between a respective pillar of the plurality of pillars 622 and the piezoelectric layer 610. Thus, for each finger (e.g., 671, 672, or the like) in the IDT of the iXBAR 600, there is a corresponding pillar (e.g., 622(1), 622(2), or the like) that is between the finger and the bulk portion 621.

Referring to FIG. 7B, when the values of the height Tₚᵢₗₗₐᵣ are smaller than a threshold (e.g., 400 nm), the Y-parameters indicate that the iXBAR 600 has a resonance frequency at approximately 4600 MHz, and an anti-resonance frequency at approximately 5200 MHz. That is, plot 714 illustrates the admittance for an iXBAR 600 having a pillar height of 300 nm and plot 712 illustrates the admittance for an iXBAR 600 having a pillar height shorter than 300 nm. On the other hand, when the values of the height Tₚᵢₗₗₐᵣ are larger than the threshold (e.g., 400 nm), the Y-parameters indicate that the iXBAR 600 has a resonance frequency at approximately 5200 MHz, and an anti-resonance frequency at approximately 6200 MHz. That is, plot 716 illustrates the admittance for an iXBAR 600 having a pillar height of 500 nm and plot 718 illustrates the admittance for an iXBAR 600 having a pillar height greater than 500 nm. As such, FIG. 7B demonstrates that a discontinuous jump (also referred to as a frequency shift) in the resonant frequency of the iXBAR 600 occurs when the thickness Tₚᵢₗₗₐᵣ varies from below the threshold to above the threshold. In an example, the discontinuous jump occurs when the thickness Tₚᵢₗₗₐᵣ is approximately the thickness of the piezoelectric layer 610 or 1/2 of the wavelength of the acoustic wave.

Moreover, it is noted that the resonance frequency of an iXBAR is dependent on the total thickness of the dielectric layers, including the piezoelectric layer 610, and dielectric layer(s) disposed over the piezoelectric layer 610. In an exemplary aspect, the thickness of one or both dielectric layers over the piezoelectric layer 610 can be varied to change the resonance frequencies of various iXBARs in a bandpass filter. In an aspect, referring back to FIG. 4A, a bandpass filter (e.g., the bandpass filter 400) can include a plurality of acoustic resonators. The plurality of acoustic resonators can include one or more series resonators (e.g., 410A, 410B, 410C, and 410D shown in FIG. 4A) and one or more shunt resonators (e.g., 420A, 420B and 420C shown in FIG. 4A). In an example, the shunt resonators in the bandpass filter can have lower resonance frequencies than the series resonators. In some examples, the shunt resonators incorporate thicker dielectric layers to reduce the resonance frequencies of the shunt resonators relative to series resonators with thinner dielectric layers.

FIG. 7B indicates a frequency jump (e.g., the frequency jump is approximately 5000 MHz) in the resonant frequency of the iXBAR 600 when the thickness Tₚᵢₗₗₐᵣ varies, for example, from 300 nm to 500 nm. This frequency jump due to the variation of the thickness of the pillars can be used, for example, alone or together with other methods (e.g., varying the total thickness of the dielectric layers including the piezoelectric layer 610) to tune the resonant frequencies of the series resonators and/or the shunt resonators and thus to achieve a frequency difference between the series and shunt resonators. For example, one of the one or more series resonators in the bandpass filter can include a first iXBAR such as the iXBAR 600 with a first thickness Tₚᵢₗₗₐᵣ₁ of the plurality of pillars in the first iXBAR. One of the one or more shunt resonators in the bandpass filter can include a second iXBAR with a second thickness Tₚᵢₗₗₐᵣ₂ of a plurality of pillars in the second iXBAR. The first thickness Tₚᵢₗₗₐᵣ₁ can be larger than the second thickness Tₚᵢₗₗₐᵣ₂ to achieve a frequency difference between the series and shunt resonators, e.g., the first and second iXBARs.

It is noted that the configurations for which the frequency of pillars are used in an iXBAR can depend on various factors, such as requirements for heat dissipation, a coupling factor, and the like. Referring back to FIG. 7A, graph 700A compares using a single pillar versus using a pair of pillars to illustrate the tradeoff. As shown, there is a tradeoff where N = 2 in plots 706 and 708 reduces and/or removes the spur at about 5800 MHz. However, the configuration for N = 1 increases the electromechanical coupling so there is a tradeoff for these configurations.

In an aspect, referring back to FIG. 2A, for a same mark (or a width) w of the fingers in the IDT, increasing a pitch p that is a center-to-center spacing along the second axis (e.g., X axis) between adjacent fingers of the plurality of interleaved fingers can mitigate spurs, and thus can be beneficial. For example, when the pitch p increases, a total contact area between the fingers and the piezoelectric layer is reduced, and thus reducing spurs. On the other hand, increasing the pitch p can reduce heat dissipation. Thus, the pitch p can be determined based on the requirements for the iXBAR. According to an aspect of the disclosure, the pitch p can be larger than a threshold, such as 10 times that of a thickness ts of the piezoelectric layer. For example, p > 10×ts. The thickness ts of the piezoelectric layer is measured along the Z axis that is perpendicular to the X and Y axes.

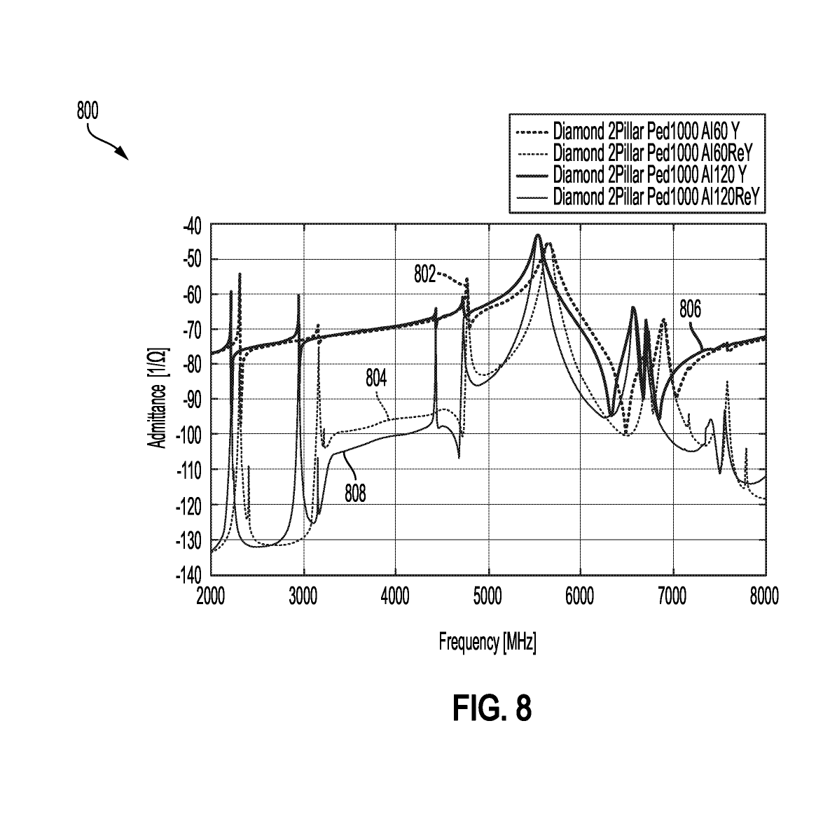

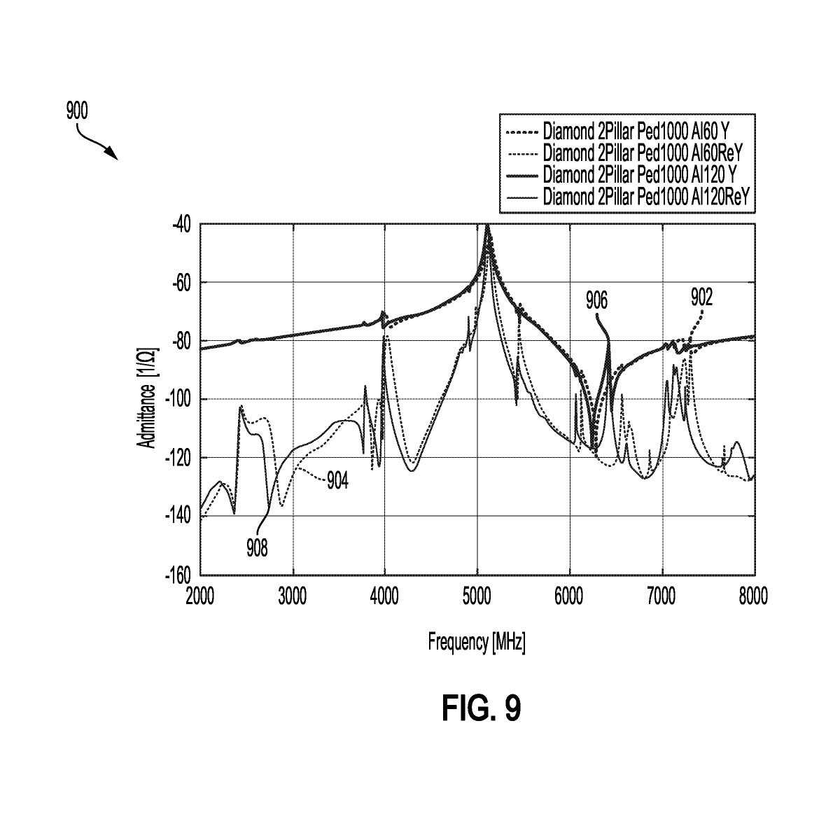

FIGS. 8-9 illustrate graphs 800 and 900, respectively, that demonstrate the effects of the pitch p according to an aspect of the disclosure. The graphs show simulated admittance curves of the iXBAR 600 versus a frequency in unit of MHz. The frequency range is from 2000 to 8000 MHz. Both ΙYΙ and Re(Y) of the Y-parameters are plotted. In the iXBAR structure 600 used in the simulations for the graphs in FIGS. 8-9, the substrate includes diamond, and for each finger in the IDT of the iXBAR 600, there is a corresponding pillar between the finger and the bulk portion 621 (i.e., N is 1).

The thickness of the pillars is 1000 nm in both simulated graphs 800 and 900. Moreover, referring specifically to graph 800, plot 802 illustrates admittance Y for a two pillar configuration having an IDT thickness of 60 nm and the plot 804 illustrates admittance Y for that double pillar configuration. Similarly, plot 806 illustrates the real admittance Re(Y) for the double pillar configuration having an IDT thickness of 120 nm and the plot 808 illustrates the real admittance Re(Y) for that configuration. Likewise, referring specifically to graph 900, plot 902 illustrates admittance Y for a two pillar configuration having an IDT thickness of 60 nm and the plot 904 illustrates admittance Y for that double pillar configuration. Similarly, plot 906 illustrates the real admittance Re(Y) for the double pillar configuration having an IDT thickness of 120 nm and the plot 908 illustrates the real admittance Re(Y) for that configuration.

The plots in graph 800 in FIG. 8 correspond to the pitch p being 5 times that of the thickness ts of the piezoelectric layer or example, p = 5×ts. The plots in graph 900 in FIG. 9 correspond to the pitch p being 10 times that of the thickness ts of the piezoelectric layer or example, p = 10×ts. The graphs in FIGS. 8 and 9 indicate that the iXBAR having the pitch of 10×ts is less lossy than the iXBAR having the pitch of 5×ts, and thus a large pitch can mitigate loss.

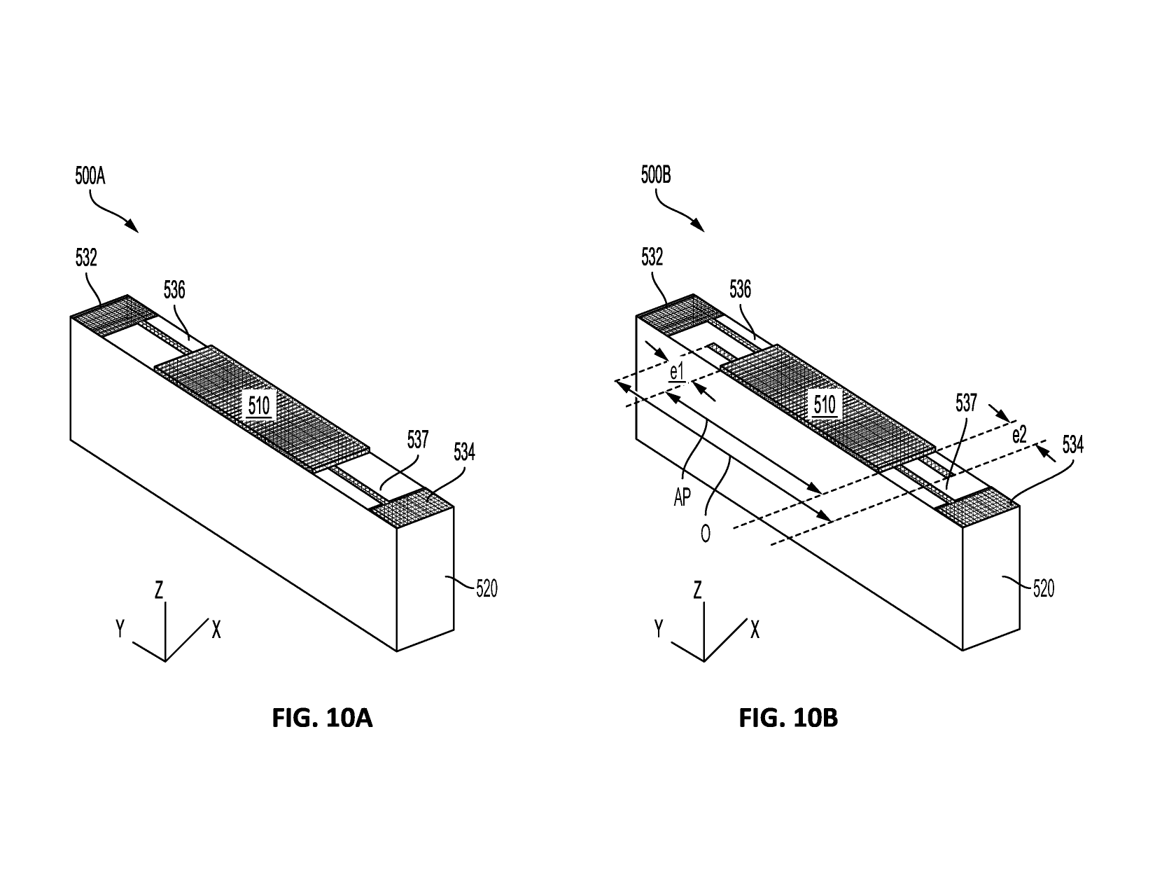

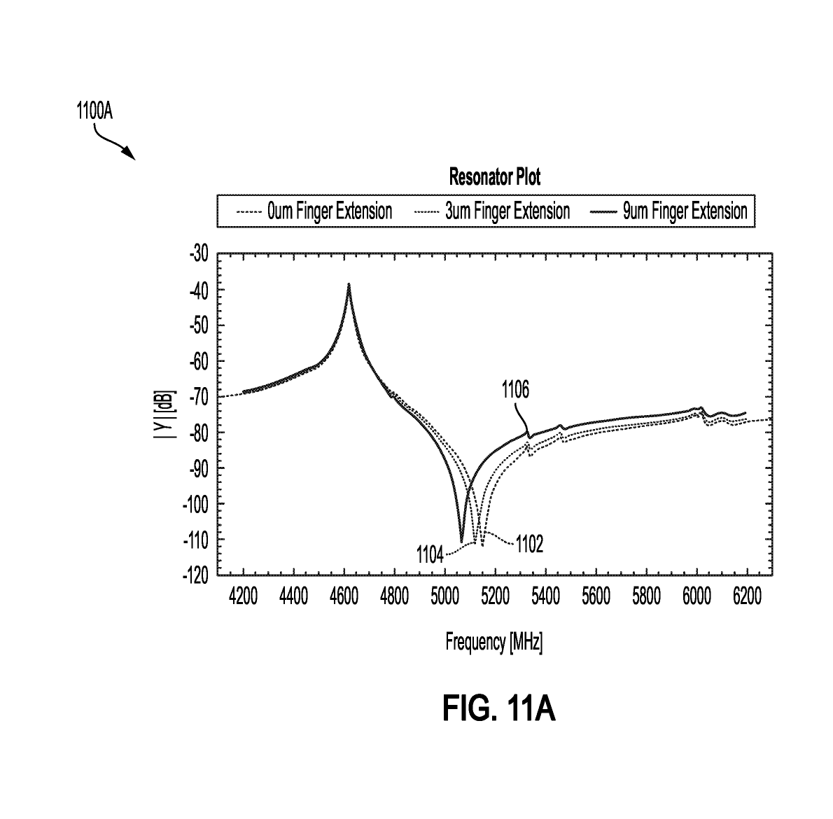

According to an aspect of the disclosure, referring back to FIGS. 5A-5B, the size AP of the piezoelectric layer 510 along the Y axis can be less than or equal to the distance O. FIG. 10A illustrates an exemplary aspect of an iXBAR 500A where the size AP of the piezoelectric layer along the Y axis is equal to the distance O. FIG. 10B illustrates an exemplary aspect of an iXBAR 500B where the size AP of the piezoelectric layer along the first axis (e.g., the Y axis) is less than the distance O. The substrate is shown below as substrate 520. Referring FIG. 10B, a total difference (AP-O) between AP and O is a sum of e1 and e2. e1 is an amount of extension of the overlapped region of the first and second plurality of fingers with respect to the piezoelectric layer along the Y axis on one side. E2 is an amount of extension of the overlapped region of the first and second plurality of fingers with respect to the piezoelectric layer along the Y axis on another side. In an example, e1 is equal to e2.

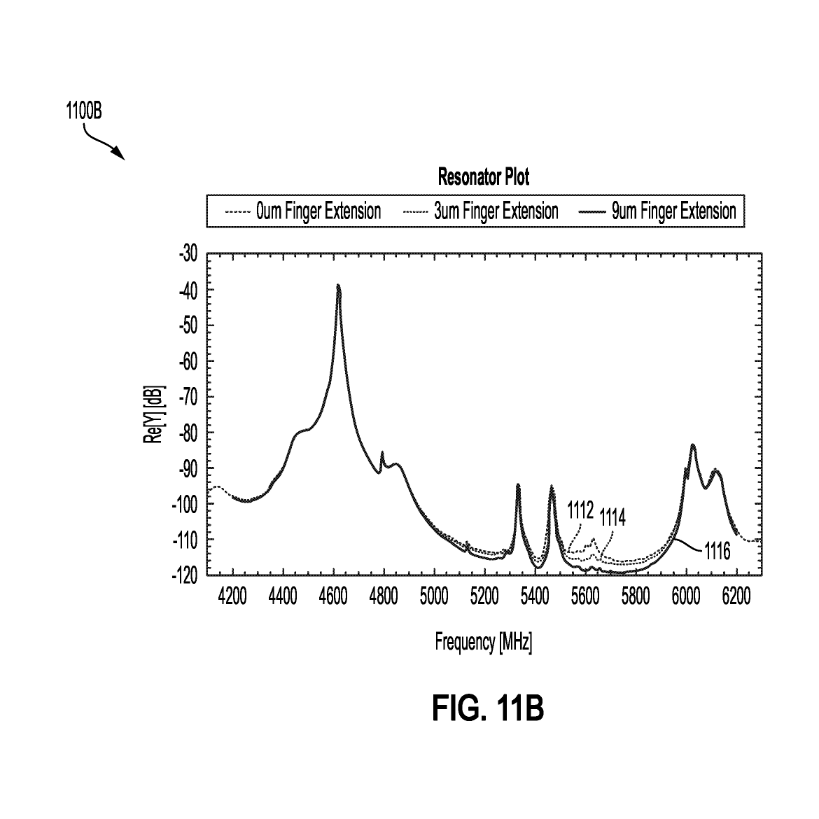

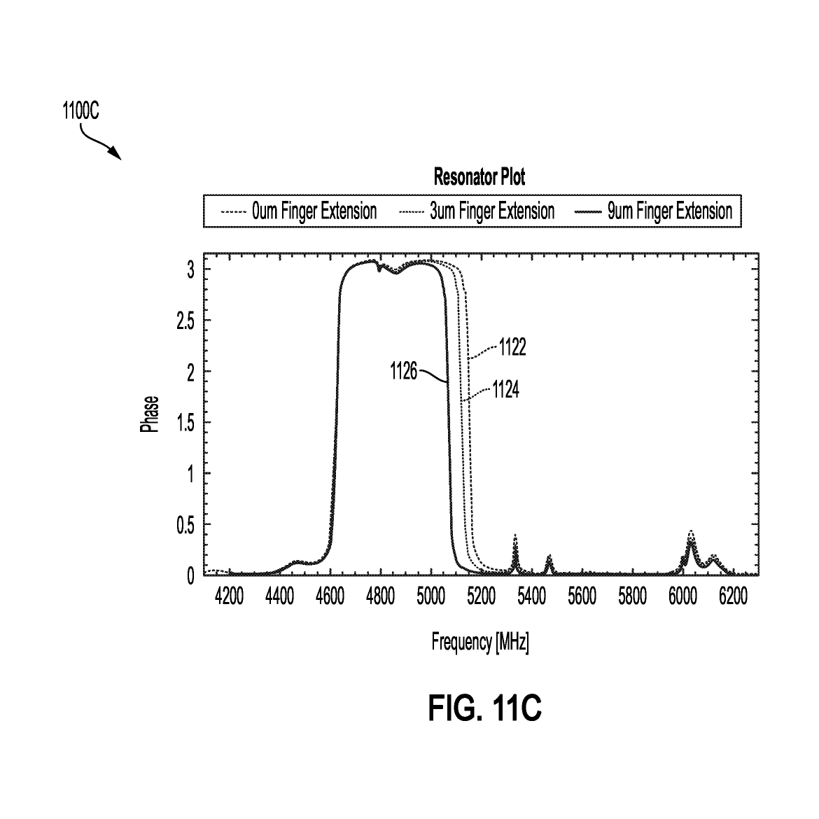

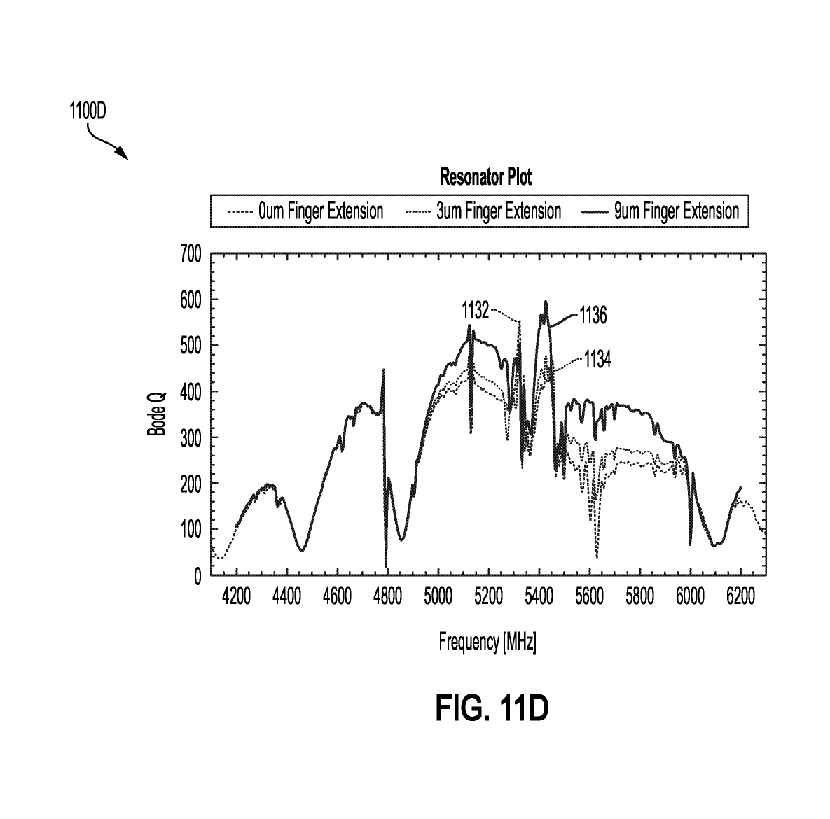

FIGS. 11A-11D show an effect of the extension e1 (or e2) according to an aspect of the disclosure. In general, the graphs 1100A, 1100B 100C and 1100D, show simulated admittance (Y-parameter) and BodeQ curves of the iXBAR versus a frequency in unit of MHz. The frequency range is from approximately 4100 to 6300 MHz. FIG. 11A is a graph 1100A illustrating the absolute value ΙYΙ of the Y-parameter. FIG. 11B is a graph 1100B illustrating the real components Re(Y) of the Y-parameter. FIG. 11C is a graph 1100C illustrating the phase. FIG. 11D is a graph 1100D illustrating BodeQ that refers to a Q factor calculated from a Bode plot and thus may indicate performance of the iXBAR.

Different graphs in each of FIGS. 11A-11D correspond to different values of the e1 (e2 is equal to e1 for FIGS. 11A-11D). The values of e1 include 0 (i.e., no extension, and AP = O), 3, and 9 micrometers (µm). In the iXBAR structure used in the simulations for the graphs in FIGS. 11A-11D, a thickness tm of the IDT fingers in the iXBAR is 120 nm, the substrate includes SiC, and each finger is disposed between a pillar that is 20 nm thick and the piezoelectric layer (e.g., N = 1).

As shown in FIG. 11A, the frequency y[db] is shown down from the plot 1102 (e1 = 0 µm) to plot 1104 (e1 = 3 µm) to plot 1106 (e1 = 9 µm). However, FIG. 11B demonstrates that that the real admittance Re[Y] reduces in at higher frequencies (e.g., between 5500 MHz to 5800 Mhz) from the plot 1112 (e1 = 0 µm) to plot 1114 (e1 = 3 µm) to plot 1116 (e1 = 9 µm). FIG. 11C also demonstrates that that the phase shifts downwards when the finger extension increases from the plot 1122 (e1 = 0 µm) to plot 1124 (e1 = 3 µm) to plot 1126 (e1 = 9 µm).

The BodeQ plots in FIG. 11D indicate that Q factors of the iXBAR increases with the amount of extension e1 within a relatively large frequency band, such as from approximately the anti-resonance frequency (about 5100 MHz) to approximately 6000 MHz. This is demonstrated when the finger extension increases from the plot 1132 (e1 = 0 µm) to plot 1134 (e1 = 3 µm) to plot 1136 (e1 = 9 µm). On the other hand, increasing e1 results in a small coupling loss as shown in FIG. 11A. When the IDT fingers go over the edge of the piezoelectric layer as shown in FIG. 10B, there is additional capacitance between the fingers, and thus resulting in a coupling loss.

Throughout this description, the embodiments and examples shown should be considered as examples, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

What is claimed:

1. A bulk acoustic resonator, comprising:
a piezoelectric layer;
a substrate; and
an interdigital transducer (IDT) including a plurality of interleaved fingers including a first plurality of fingers and a second plurality of fingers that are interleaved and are substantially parallel along a first axis, the IDT being disposed between the piezoelectric layer and the substrate,
wherein the first plurality of fingers and the second plurality of fingers overlap each other for a distance O along the first axis,
wherein a size AP of the piezoelectric layer along the first axis is less than or equal to the distance O.

2. The bulk acoustic resonator of claim 1, wherein a size of the piezoelectric layer along a second axis is a center-to-center distance L that is between outermost fingers of the plurality of interleaved fingers in the IDT, the second axis is substantially perpendicular to the first axis, an area of the piezoelectric layer is L×AP, and the piezoelectric layer is disposed within a region having an area of L×AP.

3. The bulk acoustic resonator of claim 1, wherein the substrate comprises a bulk portion and a plurality of pillars that are disposed between the piezoelectric layer and the bulk portion, and wherein one finger of the plurality of interleaved fingers is disposed between one pillar of the plurality of pillars and the piezoelectric layer.

4. The bulk acoustic resonator of claim 3, wherein each finger of the first plurality of fingers is disposed between a respective pillar of the plurality of pillars and the piezoelectric layer, and the one finger of the plurality of interleaved fingers is a finger of the first plurality of fingers.

5. The bulk acoustic resonator of claim 3, wherein each finger of the plurality of interleaved fingers is disposed between a respective pillar of the plurality of pillars and the piezoelectric layer.

6. The bulk acoustic resonator of claim 3, wherein another finger of the plurality of interleaved fingers is disposed between the bulk portion and the piezoelectric layer.

7. The bulk acoustic resonator of claim 1, wherein a pitch p that is a center-to-center spacing along a second axis between adjacent fingers of the plurality of interleaved fingers is larger than 10 times that of a thickness of the piezoelectric layer, the second axis is substantially perpendicular to the first axis, and the thickness of the piezoelectric layer is measured along an axis that is substantially perpendicular to the first axis and the second axis.

8. The bulk acoustic resonator of claim 1, wherein the size AP of the piezoelectric layer along the first axis is less than the distance O.

9. The bulk acoustic resonator of claim 1, wherein the first plurality of fingers extends from a first busbar and the second plurality of fingers extends from a second busbar, and the first busbar and the second busbar are disposed on the piezoelectric layer.

10. A bandpass filter, comprising:
a plurality of acoustic resonators comprising one or more series resonators and one or more shunt resonators,
wherein one of the one or more series resonators includes a first bulk acoustic resonator that includes:
a first piezoelectric layer;
a first substrate including a first bulk portion and a first plurality of pillars, the first plurality of pillars being disposed between the first piezoelectric layer and the first bulk portion; and
a first interdigital transducer (IDT) including a first plurality of interleaved fingers, the first IDT disposed between the first piezoelectric layer and the first substrate, one finger of the first plurality of interleaved fingers being disposed between one pillar of the first plurality of pillars and the first piezoelectric layer, and
one of the one or more shunt resonators includes a second bulk acoustic resonator that includes:
a second piezoelectric layer;
a second substrate including a second bulk portion and a second plurality of pillars, the second plurality of pillars being disposed between the second piezoelectric layer and the second bulk portion; and
a second IDT including a second plurality of interleaved fingers, the second IDT disposed between the second piezoelectric layer and the second substrate, one finger of the second plurality of interleaved fingers in the second IDT being disposed between one pillar of the second plurality of pillars and the second piezoelectric layer,
wherein a thickness of the pillar of the first plurality of pillars in the first bulk acoustic resonator is greater than a thickness of the pillar of the second plurality of pillars in the second bulk acoustic resonator.

11. The bandpass filter of claim 10, wherein:
the first plurality of interleaved fingers includes a first plurality of fingers and a second plurality of fingers that are interleaved and are substantially parallel along a first axis,
the first and second plurality of fingers of the first plurality of interleaved fingers overlap for a distance O along the first axis,
a size AP of the first piezoelectric layer along the first axis is less than or equal to the distance O,
a size of the first piezoelectric layer along a second axis is a center-to-center distance L along the second axis between outermost fingers of the first plurality of interleaved fingers,
the second axis is substantially perpendicular to the first axis, and
an area of the first piezoelectric layer is L×AP.

12. The bandpass filter of claim 10, wherein each finger of the first plurality of fingers in the first IDT is disposed between a respective pillar of the first plurality of pillars and the first piezoelectric layer, and the one finger of the first plurality of interleaved fingers is a finger of the first plurality of fingers in the first IDT.

13. The bandpass filter of claim 10, wherein each finger of the first plurality of interleaved fingers is disposed between a respective pillar of the first plurality of pillars and the first piezoelectric layer.

14. The bandpass filter of claim 10, a pitch p that is a center-to-center spacing along a second axis between adjacent fingers of the first plurality of interleaved fingers is larger than 10 times that of a thickness of the first piezoelectric layer, and the thickness of the first piezoelectric layer is measured along an axis that is substantially perpendicular to a surface of the first piezoelectric layer.

15. The bandpass filter of claim 11, wherein the size AP of the first piezoelectric layer along the first axis is less than the distance O.

16. A bulk acoustic resonator, comprising:
a piezoelectric layer;
a substrate; and
an interdigital transducer (IDT) including a plurality of interleaved fingers including a first plurality of fingers and a second plurality of fingers that are interleaved and are substantially parallel along a first axis, the IDT being disposed between the piezoelectric layer and the substrate,
wherein a pitch p that is a center-to-center spacing along a second axis between adjacent fingers of the plurality of interleaved fingers is larger than 10 times that of a thickness of the piezoelectric layer, and
wherein the second axis is substantially perpendicular to the first axis, and the thickness of the piezoelectric layer is measured along an axis that is substantially perpendicular to the first axis and the second axis.

17. The bulk acoustic resonator of claim 16, wherein the first and second plurality of fingers overlap for a distance O along the first axis, a size AP of the piezoelectric layer along the first axis is less than or equal to the distance O, a size of the piezoelectric layer along the second axis is a center-to-center distance L along the second axis between outermost fingers of the plurality of interleaved fingers in the IDT, and an area of the piezoelectric layer is L×AP.

18. The bulk acoustic resonator of claim 16, wherein the substrate comprises a bulk portion and a plurality of pillars, the plurality of pillars are disposed between the piezoelectric layer and the bulk portion, one finger of the plurality of interleaved fingers is disposed between one pillar of the plurality of pillars and the piezoelectric layer.

19. The bulk acoustic resonator of claim 18, wherein each finger of the first plurality of fingers is disposed between a respective pillar of the plurality of pillars and the piezoelectric layer, and the one finger of the plurality of interleaved fingers is a finger of the first plurality of fingers.

20. The bulk acoustic resonator of claim 18, wherein each finger of the plurality of interleaved fingers is disposed between a respective pillar of the plurality of pillars and the piezoelectric layer.
